(19) United States
(12) Patent Application Publication
(10) Pub. No.: US 2024/0128166 A1
(43) Pub. Date: Apr. 18, 2024

(54) SEMICONDUCTOR DEVICE AND POWER CONVERSION DEVICE

(71) Applicant: Mitsubishi Electric Corporation, Tokyo (JP)

(72) Inventor: Hiroyuki MASUMOTO, Tokyo (JP)

(73) Assignee: Mitsubishi Electric Corporation, Tokyo (JP)

(21) Appl. No.: 18/447,834

(22) Filed: Aug. 10, 2023

(30) Foreign Application Priority Data
Oct. 14, 2022 (JP) 2022-165466

(51) Int. Cl. H01L 23/495; H01L 23/00; H01L 23/31; H01L 23/492

(52) U.S. Cl. CPC H01L 23/49524; H01L 23/3121; H01L 23/492; H01L 23/49562; H01L 24/48; H01L 24/32; H01L 24/40; H01L 24/73; H01L 2224/32225; H01L 2224/404; H01L 2224/48175; H01L 2224/73221; H01L 2224/73263; H01L 2224/73265

(57) ABSTRACT

A semiconductor device includes a conductor having a plate shape with a first thickness, an insulator sealing a portion of the conductor, a semiconductor element sealed in the insulator and electrically connected to the portion of the conductor, and a terminal bonded to the conductor outside of the insulator. A length, along the conductor, from a section where the conductor and the terminal are bonded toward the semiconductor element to the insulator, is greater than the first thickness.

### BACKGROUND OF THE INVENTION

### Field of the Invention

The present disclosure relates to a semiconductor device and a power conversion device.

### Description of the Background Art

A technique has been proposed to suppress the decrease in reliability of a semiconductor device and a power conversion device equipped with the semiconductor device.

For example, a semiconductor module has a semiconductor unit and a case that houses the semiconductor unit, and the case includes power terminals. A connecting member electrically connects the semiconductor module and the capacitor, and mechanically connect them as well. The back surface of the connecting member is placed on the power terminal, and the connecting member is bonded to the power terminal by a weld extending from the front surface of the connecting member to the back surface. By controlling the depth of penetration of the weld, heat damage on the side opposite to the connecting member at the bonded portion is suppressed. Such a technique is disclosed, for example, in Japanese Patent Application Laid-Open No. 2022-6876.

Suppressing heat generated when a conductor that is electrically connected to a semiconductor element is bonded to a terminal from being transmitted to the semiconductor element by thermal conduction through the conductor is considered to contribute to improving the reliability not only of the semiconductor device but also of the power conversion device.

### SUMMARY

An object of the present disclosure is to make heat generated by bonding at a terminal less likely to be transmitted to a semiconductor element.

A semiconductor device according to the present disclosure includes a conductor having a plate shape with a first thickness, an insulator sealing a portion of the conductor, a semiconductor element sealed in the insulator and electrically connected to the portion of the conductor, and a terminal bonded to the conductor outside the insulator. A length, along the conductor, from a section where the conductor and the terminal are bonded toward the semiconductor element to the insulator, is greater than the first thickness.

According to the semiconductor device according to the present disclosure, heat generated by bonding at a terminal less likely to be transmitted to a semiconductor element.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a configuration of a semiconductor device according to Embodiment 1;

FIG. 2 is a perspective view illustrating a portion of the configuration of the semiconductor device according to Embodiment 1;

FIG. 3 is a plan view illustrating connection between a conductor and a semiconductor element according to Embodiment 1;

FIG. 4 is a cross-sectional view illustrating a first example of a configuration of a semiconductor device according to Embodiment 2;

FIG. 5 is a cross-sectional view illustrating a second example of a configuration of the semiconductor device according to Embodiment 2;

FIG. 6 is a cross-sectional view illustrating a third example of a configuration of the semiconductor device according to Embodiment 2;

FIG. 7 is a cross-sectional view illustrating a first example of a configuration of a semiconductor device according to Embodiment 3;

FIG. 8 is a cross-sectional view illustrating a second example of a configuration of the semiconductor device according to Embodiment 3;

FIG. 9 is a cross-sectional view illustrating a configuration of a semiconductor device according to Embodiment 4;

FIG. 10 is a perspective view illustrating an appearance of a semiconductor module and a conductor used in a semiconductor device according to Embodiment 5;

FIG. 11 is a perspective view illustrating an appearance of the semiconductor device according to Embodiment 5;

FIG. 12 is a cross-sectional view illustrating the semiconductor device at the position HH in FIG. 11; and

FIG. 13 is a block diagram illustrating a configuration of a power conversion system to which a power conversion device according to Embodiment 8 is applied.

### DESCRIPTION OF THE PREFERRED EMBODIMENTS

### Embodiment 1

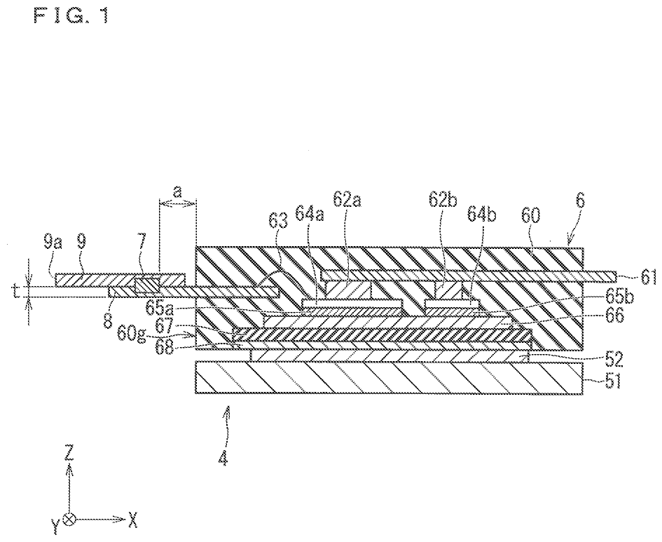

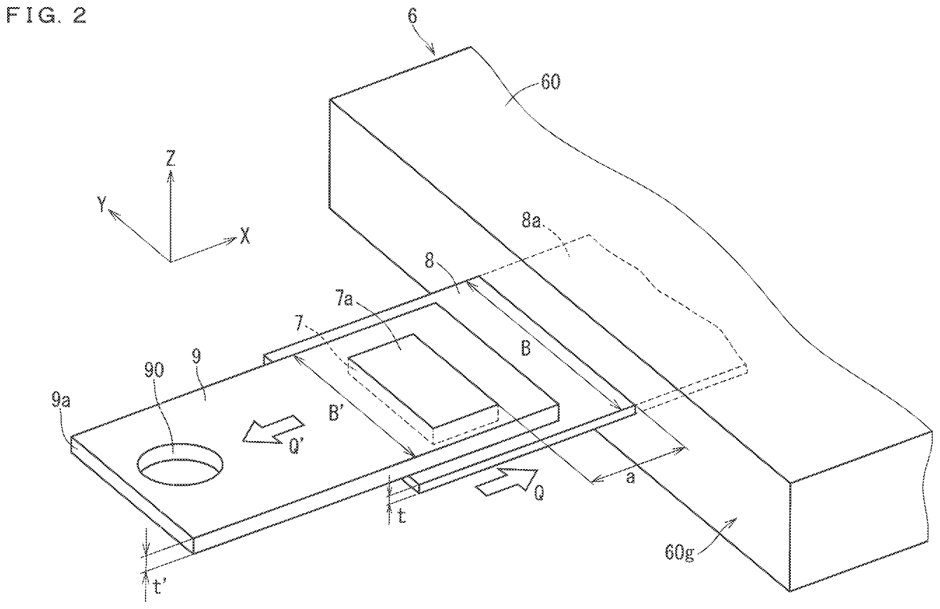

FIG. 1 is a cross-sectional view illustrating a configuration of a semiconductor device 4 according to Embodiment 1. FIG. 2 is a perspective view illustrating a portion of the configuration of the semiconductor device 4 according to Embodiment 1.

The semiconductor device 4 includes a semiconductor module 6, a conductor 8 and a terminal 9. FIG. 2 illustrates the conductor 8 and the terminal 9 and a portion of the semiconductor module 6 in the vicinity of the conductor 8 and the terminal 9. The terminal 9 may have a hole 90 on the side opposite to the semiconductor module 6 (see FIG. 2). However, illustration of the hole 90 is omitted in FIG. 1.

The semiconductor module 6 includes a semiconductor element 64a and an insulator 60. The insulator 60 functions as a sealing material that seals a portion 8a of the conductor 8 and the semiconductor element 64a. To improve visibility, indication using the reference numeral 8a for the portion 8a is omitted in FIG. 1.

The insulator 60 adopts an epoxy resin, for example. For example, the insulator 60 adopts a structure in which a gel is surrounded by a case (housing) formed of polyphenylene sulfide (PPS) or polyethylene terephthalate (PET) as its material, and the gel seals the portion 8a and the semiconductor element 64a.

The portion 8a and the semiconductor element 64a are electrically connected, for example, through wiring 63. Aluminum, for example, is adopted as the material of the wiring 63. Adoption of, for example, a bonding wire for the wiring 63 increases the degree of freedom in layout of the semiconductor element 64a and the conductor 8, and contributes to miniaturization of the semiconductor device 4.

The conductor 8 has a plate shape with a thickness t. For convenience of explanation, the thickness direction of the conductor 8 is adopted as a direction Z. A direction directing from the outside of the insulator 60 of the conductor 8 toward the portion 8a is adopted as a direction X. The direction X differs from a direction Z, and typically the direction X is orthogonal to the direction Z. In the following description, the directions X and Z are orthogonal to each other, and a direction Y, which is orthogonal to both of the directions X and Z, and constitutes the so-called right-handed coordinate system, is introduced.

The conductor 8 and the terminal 9 are formed using a material with low electrical resistance, such as copper. The terminal 9 is bonded to the conductor 8 outside of the insulator 60. The terminal 9 is bonded to the conductor 8 at a section 7. The bonding between the conductor 8 and the terminal 9 is implemented by, for example, laser bonding or soldering using a soldering iron. The insulator 60 has an end surface 60g on the section 7 side.

FIG. 2 illustrates an aspect in which the section 7 exposes a surface 7a from the terminal 9 by laser bonding from the terminal 9 side (unlike FIG. 1). For example, bonding the conductor 8 and the terminal 9 to each other by laser welding contributes to the miniaturization of the semiconductor device 4. Although laser welding generates huge heat locally, a structural feature suppresses the influence exerted on the module 6 by the heat through the conductor 8. The feature includes that a distance a being a length along the conductor 8 from the section 7 towards the semiconductor element 64a to the insulator 60 (in accordance with FIG. 1, a length between the section 7 and the end surface 60g) is greater than the thickness t. Details of the advantages of the feature will be described later.

For example, the semiconductor module 6 includes a plate-shaped conductor 61, a semiconductor element 64b, and bonding materials 62a and 62b. The conductor 61 is connected to the semiconductor element 64a through the bonding material 62a, and is connected to the semiconductor element 64b through the bonding material 62b. For example, the bonding material 62a and the conductor 61 are connected to the semiconductor element 64a on the same side (the direction Z side in the illustration of FIG. 1) with respect to the semiconductor element 64a.

For example, the semiconductor module 6 includes bonding materials 65a and 65b, a circuit pattern 66, and an insulating layer 67. The circuit pattern 66 is provided on the side of the semiconductor elements 64a and 64b with respect to the insulating layer 67.

The conductor 66 is connected to the semiconductor element 64a through the bonding material 65a, and is connected to the semiconductor element 64b through the bonding material 65b. For example, the bonding material 62a and the bonding material 65a are located on opposite sides from each other with respect to the semiconductor element 64a. For example, the bonding material 62b and the bonding material 65b are located on opposite sides from each other with respect to the semiconductor element 64a. For example, the circuit pattern 66 and the conductor 61 sandwich the semiconductor elements 64a and 64b in the Z direction.

The insulating layer 67 is formed using a resin or ceramic, for example. The conductor 61 and the circuit pattern 66 are formed using a material with low electrical resistance, such as copper. Solder or silver, for example, is adopted as the material of the bonding materials 62a, 62b, 65a, and 65b.

For example, the semiconductor module 6 includes a conductor foil 68. The conductor foil 68 is provided on the side opposite to the circuit pattern 66 with respect to the insulating layer 67.

The insulator 60 seals the semiconductor element 64b, the bonding materials 62a, 62b, 65a, and 65b, the circuit pattern 66, and the insulating layer 67. The insulator 60 seals at least the insulating layer 67 side of the conductor foil 68 and at least the portions of the conductor 61 that are bonded to the bonding materials 62a and 62b.

The insulator 60 exposes at least a portion of the conductor foil 68 on the side opposite to the insulating layer 67 to the outside of the insulator 60. For example, FIG. 1 illustrates a case where the side opposite to the direction Z of the conductor foil 68 is exposed.

The insulator 60 exposes at least a portion of the conductor 61 to the outside of the insulator 60. For example, FIG. 1 illustrates a case where the conductor 61 is exposed on the X direction side.

For example, the semiconductor device 4 includes a cooler 51 and a bonding material 52. The insulator 60 does not seal the cooler 51. The bonding material 52 bonds the cooler 51 and the conductor foil 68 exposed from the insulator 60. The cooler 51 is formed of a material with high thermal conductivity, such as aluminum or copper. Solder or silver, for example, is adopted as the material of the bonding material 52.

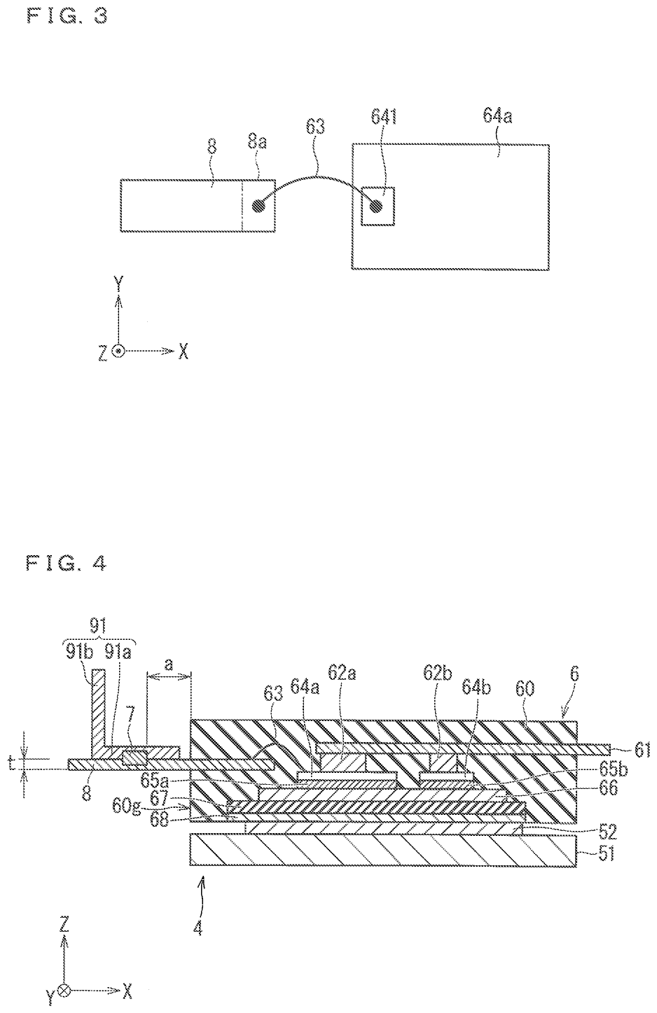

FIG. 3 is a plan view illustrating connection between the conductor 8 and the semiconductor element 64a. The illustration of the hole 90 is also omitted in FIG. 3. The semiconductor element 64a includes a control section 641. The wiring 63 ties the portion 8a and the control section 641 to connect them electrically. Adopting a bonding wire for the wiring 63 to tie the portion 8a and the control section 641 enables efficient arrangement of the wiring 63, contributing not only to improving the degree of freedom of the layout inside of the semiconductor module 6 but also to miniaturizing the semiconductor device 4.

When the terminal 9 and the conductor 8 are bonded together, the heat generated at the bonding point varies greatly depending on the bonding method. For example, when the terminal 9 adopts copper as the material thereof and subjected to keyhole welding with a laser, although locally and momentarily, the temperature of the bonded portion exceeds the melting point of copper (1000° C. or higher).

Suppression of the heat generated by bonding from being transmitted to the insulator 60 and the element sealed by the insulator 60 through the conductor 8 is desirable from the viewpoint of the reliability not only of the semiconductor module 6 and but also of the semiconductor device 4.

In this suppression, it is preferable that the distance from the section 7 to the insulator 60 or the element sealed by the insulator 60 is increased and the thickness t of the conductor 8 is made reduced so that less heat can be conducted. Simply extending the conductor 8 to increase the distance between section 7 and the insulator 60 results in expanding the space occupied not only by the conductor 8, but also by the semiconductor module 6 and the semiconductor device 4.

Reducing a width B, which is the length of the conductor 8 along the direction Y, contributes to the above suppression, but decreases the area of the section 7 in plan view. It is conceivable that such decreasing may lead to a possible decrease in bonding strength between the conductor 8 and the terminal 9, a possible decrease in mechanical reliability, and a possible decrease in electrical reliability.

A width B′ as the length of terminal 9 along the direction Y, a thickness t′ as length of terminal 9 along the direction Z, an amount of heat Qo applied to the section 7 during bonding, an amount of heat Q transferred from the section 7 to the insulator 60, an amount of heat Q′ transmitted from the section 7 toward a tip 9a of the terminal 9 on the side opposite to the insulator 60 (opposite side in the direction X), a temperature To of the section 7 during bonding, a temperature T of the insulator 60, and the temperature T′ of the tip 9a are introduced (refer to FIG. 2), the following Equations hold true.

Q_{∝}(To−T)*B*(t/a) (1)

Q′_{∝}(To−T′)*B′*t′ (2)

Q=Qo−Q′ (3)

From Equation (3), one possible solution to suppress the amount of heat Q is to increase the amount of heat Q′. However, T′>T is held during bonding, and (To-T′) on the right-hand side of Equation (2) is less than (To-T) on the right-hand side of Equation (1). Therefore, increasing the amount of heat Q′ is unrealistic to implement. For the same reason, the influence of width B′ and thickness t′ on the amount of heat Q is small.

Under these circumstances, the width B, the thickness t, and the distance a in Equation (1) are parameters that greatly affect the amount of heat Q. From the viewpoint of obtaining bonding strength, it is desirable to increase the area of the section 7 in plan view. Therefore, reducing the widths B and B′ is also unrealistic to implement.

Thus, the feature of the distance a being greater than the thickness t as described above suppresses the amount of heat from transmitting to the semiconductor module 6. The heat generated by bonding at the terminal 9 is less likely to be transmitted to the semiconductor element 64a, which improves the reliability not only of the semiconductor element 64a but also of the semiconductor device 4.

### Embodiment 2

FIG. 4 is a cross-sectional view illustrating a first example of a configuration of a semiconductor device 4 according to Embodiment 2. A semiconductor module 6 and a conductor 8 of the semiconductor device 4 according to Embodiment 2 are configured in the same manner as the semiconductor module 6 and the conductor 8 of the semiconductor device 4 according to Embodiment 1. The semiconductor device 4 according to Embodiment 2 includes a terminal 91 instead of the terminal 9 of the semiconductor device 4 according to Embodiment 1.

The terminal 91 has a first portion 91a and a second portion 91b. The first portion 91a is in contact with the conductor 8 and is bonded to the conductor 8. For example, the first portion 91a contacts the conductor 8 on the direction Z side of the conductor 8. The section 7 is located between the first portion 91a and the conductor 8, for example. When laser bonding is adopted to bond the first portion 91a and the conductor 8, the section 7a is exposed from the terminal 9 as illustrated in FIG. 2.

The second portion 91b is linked to the first portion 91a and is bent with respect to the first portion 91a. For example, in the semiconductor device 4 according to the first example of Embodiment 2, the second portion 91b is farther away from the semiconductor module 6 than the first portion 91a is. For example, the second portion 91b extends from the first portion 91a in a direction away from the conductor 8 (direction Z in FIG. 4).

In comparison with the terminal 9, with the terminal 91, the degree of freedom in layout improves not only with respect to the conductor 8, but also with respect to the semiconductor module 6. This improvement contributes to miniaturization of the semiconductor device 4. Due to the presence of the second portion 91b, the terminal 91 can more easily increase volume compared to the terminal 9. The increase in volume causes an increase in the heat capacity of the terminal 91, and the amount of heat transferred to the terminal 91 out of the amount of heat from the section 7 increases. An increase in the amount of heat transferred to the terminal 91 contributes to the suppression of not only the amount of heat transferred to the semiconductor module 6 but also the amount of heat transferred to the semiconductor element 64a (see Equation (3)).

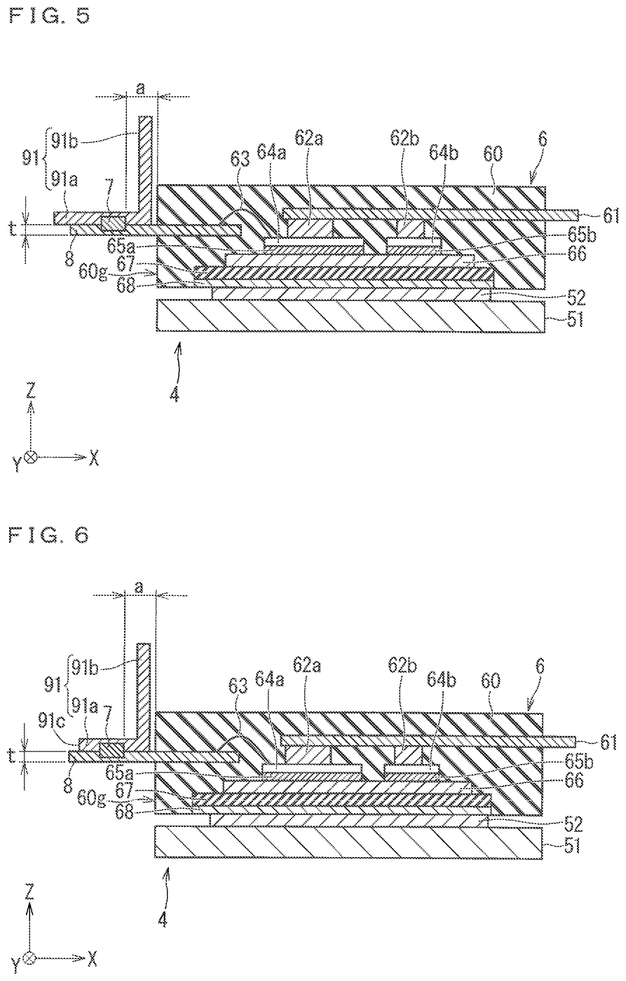

FIG. 5 is a cross-sectional view illustrating a second example of a configuration of the semiconductor device 4 according to Embodiment 2. In the semiconductor device 4 according to the second example of Embodiment 2, the first portion 91a and the second portion 91b are linked nearer to the semiconductor module 6 than the section 7, hence, nearer to the semiconductor element 64a than the section 7.

Compared to the first example, the second example is advantageous in that it is easier to establish the relationship a>t, and is more advantageous in that it is easier to suppress the conduction of heat to the semiconductor module 6 and further to the semiconductor element 64a.

FIG. 6 is a cross-sectional view illustrating a third example of a configuration of the semiconductor device 4 according to Embodiment 2. The third example of Embodiment 2 has a feature where the first portion 91a has an end surface 91c on the conductor 8 on the side opposite to the second portion 91b in the second example of Embodiment 2. Compared to the second example in which the end surface 91c is separated from the conductor 8 when viewed from the semiconductor module 6, the third example contributes to miniaturization of the semiconductor device 4 in addition to the effect of the second example.

### Embodiment 3

In the semiconductor device 4 according to Embodiment 3, as in the second and third examples of the semiconductor device 4 according to Embodiment 2, a terminal 91 is adopted, the first portion 91a is bonded to the conductor 8, and the first portion 91a and the second portion 91b are linked nearer to the semiconductor element 64a than the section 7.

In the semiconductor device 4 according to Embodiment 3, the second portion 91b sandwiches the conductor 8 between the second portion 91b per se and the insulator 60 in the direction Z, which is the direction in which the length of the conductor 8 is the thickness t.

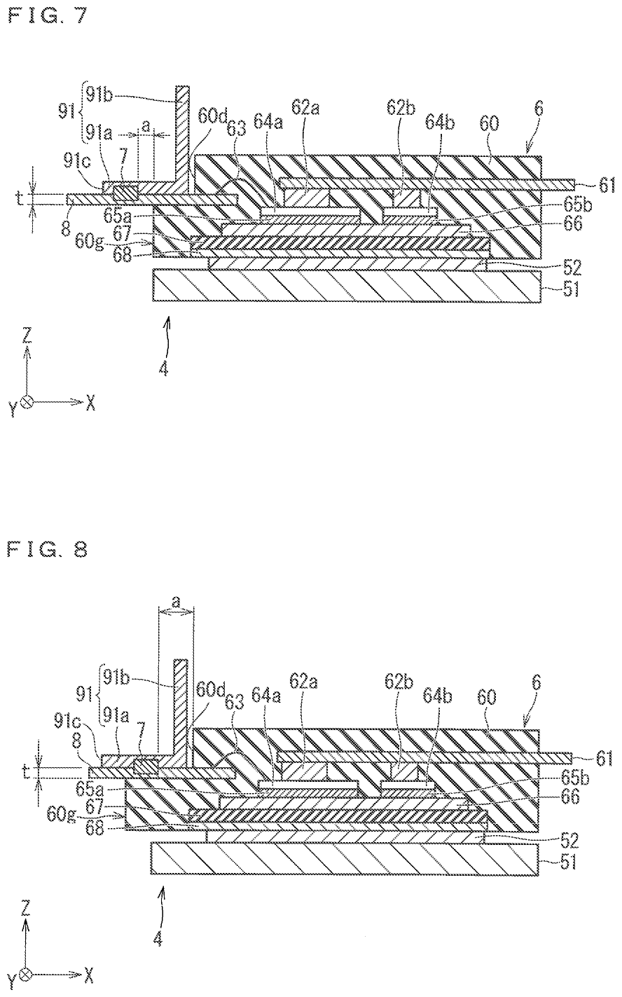

FIG. 7 is a cross-sectional view illustrating a first example of a configuration of a semiconductor device 4 according to Embodiment 3. FIG. 7 illustrates a case where the end surface 91c is on the conductor 8, as in the third example of the semiconductor device 4 according to Embodiment 2. The end surface 91c may be separated from the conductor 8 when viewed from the semiconductor module 6.

FIG. 7 illustrates a case where the insulator 60 has an internal corner 60d, and the second portion 91b sandwiches the conductor 8 between the second portion 91b per se and the insulator 60 in the direction Z at the internal corner 60d. The second portion 91b being at the position where it sandwiches the conductor 8 between the second portion 91b per se and the insulator 60 contributes not only to reduction in the length of the conductor 8 protruding from the insulator 60, but also to miniaturization of the semiconductor device 4. The presence of the internal corner 60d contributes to the second portion 91b sandwiching the conductor 8 between the second portion 91b per se and the insulator 60.

Also in the case of the insulator 60 having the internal corner 60d, the distance a is the length along conductor 8 from the section 7 toward the semiconductor element 64a to the insulator 60. Therefore, also in the first example of the configuration of the semiconductor device 4 according to Embodiment 3, as in Embodiments 1 and 2, the distance a is the length along conductor 8 between the section 7 and the end surface 60g.

FIG. 8 is a cross-sectional view illustrating a second example of a configuration of the semiconductor device 4 according to Embodiment 3. In the second example of the configuration of the semiconductor device 4 according to Embodiment 3, the section 7 aligns with the insulator 60 along the Z direction. Arrangement of the section 7 in this manner contributes not only to reduction in the length of the conductor 8 protruding from the insulator 60, but also to miniaturization of the semiconductor device 4.

Also in the case of the section 7 aligning with the insulator 60 along the Z direction, the distance a is the length along conductor 8 from the section 7 toward the semiconductor element 64a to the insulator 60. In this case, therefore, the distance a is not the length along the conductor 8 between the section 7 and the end surface 60g. In this case, the distance a is the length between the section 7 and an end surface at which the insulator 60 appears on the section 7 side at the internal corner 60d (the surface in contact with the tip of the leader line indicating the internal corner 60d in FIG. 8).

In the second example of the configuration of the semiconductor device 4 according to Embodiment 3, the temperature of the insulator 60 is likely to rise since the insulator 60 is directly below the section 7 (on the opposite side of the direction Z). However, the heat transfer to the semiconductor element 64a is effected via the conductor 8; therefore, the heat transfer is suppressed by the relationship a>t as described above.

Considering the effect of the heat transferred to the insulator 60 per se, the conductor 8 and the terminal 91 are bonded using a bonding method that allows a relatively low bonding temperature, such as soldering using a soldering iron. For example, the insulator 60 adopts a material with high heat resistance.

### Embodiment 4

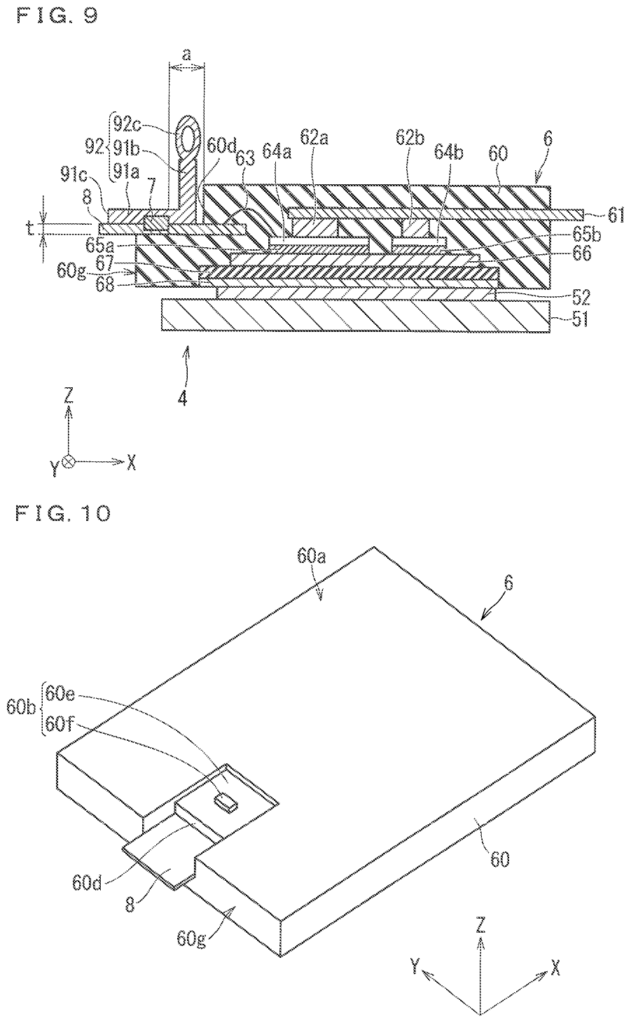

FIG. 9 is a cross-sectional view illustrating a configuration of a semiconductor device 4 according to Embodiment 4. The semiconductor device 4 according to Embodiment 4 includes a terminal 92 instead of the terminal 91 of the semiconductor device 4 adopted in the semiconductor device 4 according to Embodiment 2.

The terminal 92 has a first portion 91a and a second portion 91b as with the terminal 91. The terminal 92 is a press-fit terminal in which the second portion 91b has an insertion portion 92c on the side opposite to the first portion 91a.

In FIG. 9, as in the second example of the semiconductor device 4 according to Embodiment 2 and the semiconductor device 4 according to Embodiment 3, a case where the first portion 91a and the second portion 91b are linked nearer to the semiconductor element 64a than the section 7 is illustrated. When the first portion 91a and the second portion 91b are linked away from the semiconductor element 64a than the section 7 (see FIG. 4), the second portion 91b may have the insertion portion 92c on the side opposite to the first portion 91a.

The insertion portion 92c is inserted into an unillustrated object (inserted portion) to contribute to conduction between the object and the semiconductor element 64a via not only the terminal 92 but also the conductor 8 and the wiring 63. The insertion portion 92c contributes to mechanical fixation between the object and the semiconductor module 6 via not only the terminal 92 but also the conductor 8. Adopting the terminal 92, which is a press-fit terminal, contributes to widening options during assembly in a power conversion device (which will be exemplified later) on which the semiconductor device 4 is mounted, and contributes not only to an increase in the degree of freedom in arranging the semiconductor device 4 but also to the miniaturization of a unit in which the power conversion device is used.

### Embodiment 5

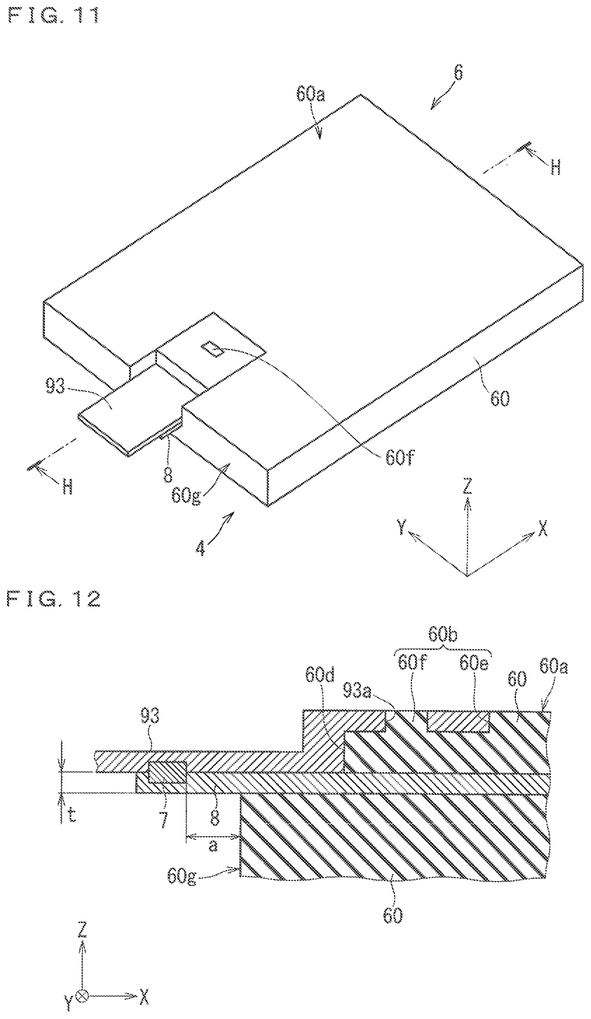

FIG. 10 is a perspective view illustrating an appearance of a semiconductor module 6 and a conductor 8 included in a semiconductor device 4 according to Embodiment 5. FIG. 11 is a cross-sectional view illustrating the semiconductor device 4 according to Embodiment 5. FIG. 12 is a cross-sectional view of the semiconductor device 4 viewed along the direction Y at the position HH in FIG. 11.

The semiconductor device 4 according to Embodiment 5 includes a terminal 93 instead of the terminals 9, 91, and 92 described above. The terminal 93 is bonded to the conductor 8 at a section 7.

The insulator 60 has unevenness 60b. FIGS. 10, 11 and 12 illustrate the case where the unevenness 60b appears on the direction Z side more than the conductor 8. Also in these figures, although the insulator 60 also has an internal corner 60d, the presence of the internal corner 60d is not essential in Embodiment 5.

The unevenness 60b includes a concave portion 60e and a protrusion 60f. The concave portion 60e is recessed with respect to the main end surface 60a of the insulator 60 in the Z direction. For example, concave portion 60e is continuous with the internal corner 60d. The protrusion 60f protrudes from the concave portion 60e, for example, in the direction Z.

The terminal 93 has a concave portion 93a that fits with the protrusion 60f. For example, the concave portion 93a is a hole extending through the terminal 93, and when the terminal 93 is in a state of bonded to the conductor 8, the protrusion 60f is exposed from the recess 93a.

Also in Embodiment 5, the distance a is described as the length along the conductor 8 from the section 7 toward the semiconductor element 64a to the insulator 60. Specifically, for example, the distance a is the length between the section 7 and the end surface 60g of the insulator 60 on the section 7 side.

The protrusion 60f and the concave portion 93a fitting with each other improves the positional accuracy of the terminal 93, stabilizes the bonding quality at the section 7, contributing to miniaturization of the semiconductor device 4 and improvement in reliability thereof.

### Embodiment 6

In any of the semiconductor devices 4 of Embodiments 1 to 5, the semiconductor element 64a includes, for example, a Reverse Conducting Insulated Gate Bipolar Transistor (RC-IGBT). For example, the semiconductor element 64a is a reverse conducting insulated gate bipolar transistor. Similarly, the semiconductor element 64b may also include a reverse conducting insulated gate bipolar transistor, and the semiconductor element 64b may be a reverse conducting insulated gate bipolar transistor. Alternatively, the semiconductor element 64b may be omitted.

The semiconductor element 64a including the reverse conducting insulated gate bipolar transistor, reduces the number of chips included in the semiconductor device 4, contributing to miniaturization of the semiconductor device 4.

### Embodiment 7

In any of the semiconductor devices 4 of Embodiments 1 to 5, the semiconductor element 64a contains silicon carbide (SiC) as a semiconductor, for example. Similarly, the semiconductor element 64b may also contain silicon carbide (SiC) as a semiconductor.

Adopting silicon carbide as a semiconductor reduces loss in the semiconductor device 4, contributing to miniaturization and higher density of the semiconductor device 4.

### Embodiment 8

In Embodiment 8, the semiconductor device 4 according to the above-described Embodiments 1 to 7 are applied to a power conversion device. Although the application of the present disclosure is not limited to a specific power conversion device, hereinafter, a case where the present disclosure is applied to a three-phase inverter will be described.

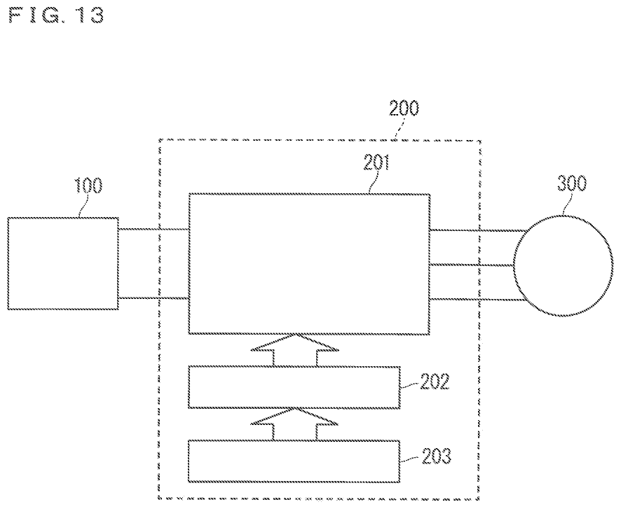

FIG. 13 is a block diagram illustrating a configuration a power conversion system to which the power conversion device of the Embodiment 8 is applied.

The power conversion system illustrated in FIG. 13 includes a power supply 100, a power conversion device 200, and a load 300. The power supply 100 is a DC power supply and supplies DC power to the power conversion device 200. The power supply 100 can be configured with various components, for example, the configuration thereof may include a DC system, a solar cell, and a storage battery, or include a rectifier circuit connected to an AC system or include an AC/DC converter. Further, the power supply 100 may be configured by a DC/DC converter that converts the DC power output from the DC system into a predetermined power.

The power conversion device 200 is a three-phase inverter connected between the power supply 100 and the load 300, which converts the DC power supplied from the power supply 100 into AC power and supplies the AC power to the load 300. As illustrated in FIG. 13, the power conversion device 200 includes a main conversion circuit 201 that converts DC power into AC power and outputs thereof, a drive circuit 202 that outputs a drive signal for driving each switching element of the main conversion circuit 201, and a control circuit 203 that outputs a control signal for controlling the drive circuit 202 to the drive circuit 202.

The load 300 is a three-phase electric motor driven by AC power supplied from the power conversion apparatus 200. The load 300 is not limited to a specific application, and is an electric motor mounted on various electric devices. For example, the load 300 is used as an electric motor for a hybrid vehicle, an electric vehicle, a railroad vehicle, an elevator, or an air conditioning device.

Hereinafter, the power conversion device 200 will be described in detail. The main conversion circuit 201 includes a switching element and a freewheeling diode (not illustrated), and by switching the switching element, the DC power supplied from the power supply 100 is converted into AC power and supplied thereof to the load 300. There are various specific circuit configurations of the main conversion circuit 201, and the main conversion circuit 201 according to Embodiment 8 is a two-level three-phase full bridge circuit, and has six switching elements and six freewheeling diodes each of which is anti-parallel with the respective switching elements. For each switching element of the main conversion circuit 201, the semiconductor device 4 according to any one of Embodiments 1 to 7 described above is applied. Each of the two switching elements connected in series of the six switching elements constitutes an upper and lower arm, and each set of upper and lower arms constitutes each phase (U phase, V phase, W phase) of the full bridge circuit. Further, the output terminal of each set of upper and lower arms, that is, the three output terminals of the main conversion circuit 201, are connected to the load 300.

The drive circuit 202 generates a drive signal for driving the switching elements of the main conversion circuit 201 and supplies the drive signal to the control electrodes of the switching elements of the main conversion circuit 201. Specifically, the drive circuit 202 outputs a drive signal for turning on the switching element and a drive signal for turning off the switching element to the control electrode of each switching element in response to the control signal from the control circuit 203 described later. When the switching element is kept in the ON state, the drive signal is a voltage signal (ON signal) equal to or higher than a threshold voltage of the switching element, and when the switching element is kept in the OFF state, the drive signal is a voltage signal (OFF signal) equal to or lower than the threshold voltage of the switching element.

The control circuit 203 controls the switching elements of the main conversion circuit 201 so that the desired power is supplied to the load 300. Specifically, the time (ON time) for each switching element of the main conversion circuit 201 to be in the ON state is calculated based on the power to be supplied to the load 300. For example, the main conversion circuit 201 is controlled by PWM control that modulates the ON time of the switching elements according to the voltage to be output. Further, a control command (a control signal) is output from the control circuit 203 to the drive circuit 202 so that an ON signal is output to the switching element to be turned on and an OFF signal is output to the switching element to be turned off at each time point. The drive circuit 202 outputs an ON signal or an OFF signal as a drive signal to the control electrode of each switching element according to the control signal.

The semiconductor device 4 according to Embodiments 1 to 7 is applied as the switching element of the main converter circuit 201 in the power conversion device according to Embodiment 8, miniaturizing the power conversion device.

The Embodiment 8 is not limited to the case where the semiconductor device 4 is applied to the two-level three-phase inverter described above, and includes cases where the semiconductor device 4 is applied to various power conversion devices. In addition to the two-level power conversion device described above, the semiconductor device 4 may be applied to a three-level or multi-level power conversion device, or when power is supplied to a single-phase load, the semiconductor device 4 may be applied to a single-phase inverter. Further, when supplying power to a DC load or the like, the semiconductor device 4 is adoptable to the DC/DC converter or the AC/DC converter.

Further, the power conversion device to which the semiconductor device 4 is applied is not limited to the case where the load is an electric motor. For example, the power conversion device can be used as a power supply device that supplies power to an electric discharge machine, a laser processing machine, an induction heating cooker, or a non-contact device power supply system. The power conversion device can be used as a power conditioner for a photovoltaic power generation system, an electric storage system, or the like.

The Embodiments can be arbitrarily combined, appropriately modified or omitted.

Hereinafter, various aspects of the present disclosure will be collectively described as Appendices.
(Appendix 1)
A semiconductor device comprising:
a conductor having a plate shape with a first thickness;
an insulator sealing a portion of the conductor;
a semiconductor element sealed in the insulator and electrically connected to the portion; and
a terminal bonded to the conductor outside of the insulator, wherein
a length, along the conductor, from a section where the conductor and the terminal are bonded toward the semiconductor element to the insulator, is greater than the first thickness.
(Appendix 2)
The semiconductor device according to Appendix 1, wherein
the terminal includes
a first portion in contact with the conductor and bonded to the conductor, and
a second portion linked to the first portion and bent with respect to the first portion.
(Appendix 3)
The semiconductor device according to Appendix 2, wherein
the terminal is a press-fit terminal having an insertion portion on a side of the second portion that is opposite to the first portion.
(Appendix 4)
The semiconductor device according to Appendix 2, wherein
the first portion and the second portion are linked nearer to the semiconductor element than the section.
(Appendix 5)
The semiconductor device according to Appendix 4, wherein
the first portion has an end surface on the conductor on a side opposite to the second portion.
(Appendix 6)
The semiconductor device according to Appendix 5, wherein
the conductor has the first thickness along a first direction, and
the second portion sandwiches the conductor between the second portion per se and the insulator in the first direction.
(Appendix 7)
The semiconductor device according to Appendix 6, wherein
the insulator has an internal corner, and,
in the internal corner, the second portion sandwiches the conductor between the second portion per se and the insulator in the first direction.
(Appendix 8)
The semiconductor device according to Appendix 7, wherein
the section aligns with the insulator along the first direction.
(Appendix 9)
The semiconductor device according to any one of Appendices 1 to 8, wherein
the insulator has a protrusion, and
the terminal has a concave portion that fits with the protrusion.
(Appendix 10)
The semiconductor device according to any one of Appendices 1 to 9, further comprising
a bonding wire connecting the portion and the semiconductor element.
(Appendix 11)
The semiconductor device according to Appendix 10, wherein
the semiconductor device includes a control section, and
the bonding wire ties the portion and the control section.
(Appendix 12)
The semiconductor device according to any one of Appendices 1 to 11, wherein
the section is obtained by laser welding.
(Appendix 13)
The semiconductor device according to any one of Appendices 1 to 12, wherein
the semiconductor element includes a reverse conducting insulated gate bipolar transistor.
(Appendix 14)
The semiconductor device according to any one of Appendices 1 to 12, wherein
the semiconductor element contains silicon carbide as a semiconductor.
(Appendix 15)
A power conversion device comprising:
a main conversion circuit including a semiconductor device according to any one of Appendices 1 to 14, and configured to convert and output input power;
a drive circuit configured to output a drive signal for driving the semiconductor device to the semiconductor device; and
a control circuit configured to output a control signal for controlling the drive circuit to the drive circuit.

While the invention has been illustrated and described in detail, the foregoing description is in all aspects illustrative and not restrictive. It is therefore understood that numerous modifications and variations can be devised without departing from the scope of the invention.

What is claimed is:

1. A semiconductor device comprising:
a conductor having a plate shape with a first thickness;
an insulator sealing a portion of the conductor,
a semiconductor element sealed in the insulator and electrically connected to the portion; and
a terminal bonded to the conductor outside of the insulator, wherein
a length, along the conductor, from a section where the conductor and the terminal are bonded toward the semiconductor element to the insulator, is greater than the first thickness.

2. The semiconductor device according to claim 1, wherein
the terminal includes
a first portion in contact with the conductor and bonded to the conductor, and
a second portion linked to the first portion and bent with respect to the first portion.

3. The semiconductor device according to claim 2, wherein
the terminal is a press-fit terminal having an insertion portion on a side of the second portion that is opposite to the first portion.

4. The semiconductor device according to claim 2, wherein
the first portion and the second portion are linked nearer to the semiconductor element than the section.

5. The semiconductor device according to claim 4, wherein
the first portion has an end surface on the conductor on a side opposite to the second portion.

6. The semiconductor device according to claim 5, wherein
the conductor has the first thickness along a first direction, and
the second portion sandwiches the conductor between the second portion per se and the insulator in the first direction.

7. The semiconductor device according to claim 6, wherein
the insulator has an internal corner, and,
in the internal corner, the second portion sandwiches the conductor between the second portion per se and the insulator in the first direction.

8. The semiconductor device according to claim 7, wherein
the section aligns with the insulator along the first direction.

9. The semiconductor device according to claim 1, wherein
the insulator has a protrusion, and
the terminal has a concave portion that fits with the protrusion.

10. The semiconductor device according to claim 1, further comprising
a bonding wire connecting the portion and the semiconductor element.

11. The semiconductor device according to claim 10, wherein
the semiconductor device includes a control section, and
the bonding wire ties the portion and the control section.

12. The semiconductor device according to claim 1, wherein
the section is obtained by laser welding.

13. The semiconductor device according to claim 1, wherein
the semiconductor element includes a reverse conducting insulated gate bipolar transistor.

14. The semiconductor device according to claim 1, wherein
the semiconductor element contains silicon carbide as a semiconductor.

15. A power conversion device comprising:
a main conversion circuit including a power semiconductor device according to claim 1, and configured to convert and output input power;
a drive circuit configured to output a drive signal for driving the semiconductor device to the semiconductor device; and
a control circuit configured to output a control signal for controlling the drive circuit to the drive circuit.
